(19) United States
(12) Patent Application Publication
(10) Pub. No.: US 2025/0373248 A1
(43) Pub. Date: Dec. 4, 2025

(54) BUS CAPACITANCE REDUCTION FOR CONTROLLER AREA NETWORK TRANSCEIVER

(71) Applicant: TEXAS INSTRUMENTS INCORPORATED, Dallas, TX (US)

(72) Inventors: Anupam BISWAS, Kolkata (IN); Deep BANERJEE, Bangalore (IN); Lokesh Kumar GUPTA, Bangalore (IN); Vikas Kumar THAWANI, Bengaluru (IN)

(21) Appl. No.: 18/677,023

(22) Filed: May 29, 2024

(51) Int. Cl. H03K 19/21; H03K 3/037; H03K 17/687; H04L 12/40

(52) U.S. Cl. CPC H03K 19/21; H03K 3/037; H03K 17/6871; H04L 12/40; H04L 2012/40215

(57) ABSTRACT

In some examples, a circuit includes a first transistor, a second transistor, a first resistor, and a digital logic circuit. The first transistor has a control terminal and first and second terminals. The second transistor has a control terminal and first and second terminals, the first terminal of the second transistor coupled to the second terminal of the first transistor. The first resistor has first and second terminals, the first terminal of the first resistor coupled to the control terminal of the second transistor, and the second terminal of the first resistor coupled to the first terminal of the second transistor. The digital logic circuit has an output terminal and first and second input terminals, the output terminal of the digital logic circuit coupled to the control terminal of the second transistor, the first input terminal of the digital logic circuit coupled to a data transmit input terminal of the circuit, and the second input terminal of the digital logic circuit coupled to a data receive output terminal of the circuit.

### BACKGROUND

Controller area network (CAN) is a communication bus protocol that enables communication between devices coupled to the bus, such as microcontrollers or other devices. The CAN protocol is a broadcast, message-based, protocol in which a highest priority device continues transmission while other lower priority devices cease transmission in the event of multiple devices attempting transmission at the same time.

### SUMMARY

In some examples, a circuit includes a first transistor, a second transistor, a first resistor, and a digital logic circuit. The first transistor has a control terminal and first and second terminals. The second transistor has a control terminal and first and second terminals, the first terminal of the second transistor coupled to the second terminal of the first transistor. The first resistor has first and second terminals, the first terminal of the first resistor coupled to the control terminal of the second transistor, and the second terminal of the first resistor coupled to the first terminal of the second transistor. The digital logic circuit has an output terminal and first and second input terminals, the output terminal of the digital logic circuit coupled to the control terminal of the second transistor, the first input terminal of the digital logic circuit coupled to a data transmit input terminal of the circuit, and the second input terminal of the digital logic circuit coupled to a data receive output terminal of the circuit.

In some examples, a circuit includes a first transistor, a second transistor, a first resistor, a digital logic circuit, a pull-up circuit, and a pull-down circuit. The first transistor has a control terminal and first and second terminals. The second transistor has a control terminal and first and second terminals, the first terminal of the second transistor coupled to the second terminal of the first transistor. The first resistor has first and second terminals, the first terminal of the first resistor coupled to the control terminal of the second transistor, and the second terminal of the first resistor coupled to the first terminal of the second transistor. The digital logic circuit has an output coupled to the control terminal of the second transistor. The digital logic circuit is configured to detect an arbitration loss or win by the circuit, responsive to detecting an arbitration loss, provide a gate control signal having a logic high value to the control terminal of the second transistor, and responsive to not detecting an arbitration loss, or to detecting an arbitration win, provide the gate control signal having a logic low value to the control terminal of the second transistor. The pull-up circuit is configured to, responsive to the gate control signal having the logic low value, pull up the first terminal of the first transistor to a supply voltage to precharge the first terminal of the second transistor. The pull-down circuit is configured to, responsive to the gate control signal having the logic high value, pull down the control terminal of the second transistor to a specified voltage.

In some examples, a method implemented in a communication transceiver includes detecting a transmission arbitration status of the communication transceiver. The method also includes responsive to the arbitration status being an arbitration loss, modifying operation of the communication transceiver.

### BRIEF DESCRIPTION OF THE DRAWINGS

FIG. 1 is a block diagram of an example system implementing a controller area network (CAN).

FIG. 2 is a diagram of example CAN communication.

FIG. 3 is a schematic diagram of an example CAN transceiver.

FIG. 4 is a schematic diagram of an example arbitration detection circuit.

FIG. 5 is a flowchart of an example method of parasitic capacitance reduction of a CAN transceiver.

### DETAILED DESCRIPTION

As described above, controller area network (CAN) is a communication bus protocol that enables communication between devices coupled to the bus, such as microcontrollers or other devices. The CAN protocol is a broadcast, message-based, protocol in which a highest priority device continues transmission while other lower priority devices cease transmission in the event of multiple devices attempting transmission at the same time. For example, multiple transmitting CAN devices undergo an arbitration process in which the highest priority CAN device continues transmitting while other CAN devices cease transmitting for a programmed amount of time. In some examples, each CAN device is assigned an identifier having a correspondence to a priority of that CAN device in the overall network. Each CAN device may include its identifier in a message being transmitted by the CAN device, such as at a beginning of the message, following a start bit of the message, or the like. By comparing a data bit on the CAN bus to a current data bit of its identifier that a CAN bus is transmitting, the CAN bus can determine whether it has lost arbitration and should cease transmitting.

Even in circumstances in which a CAN device loses arbitration and ceases transmitting, that CAN device may cause capacitive loading on the CAN bus. For example, a CAN device, such as a CAN transceiver, may include multiple switches in a driver stack that drives output signals of the CAN device, such as a n-channel metal oxide semiconductor field effect transistor (NMOS) and a p-channel metal oxide semiconductor field effect transistor (PMOS), such as a drain-extended PMOS (DEPMOS). That DEPMOS may include a comparatively large parasitic capacitance that may load the CAN bus in an amount greater than at least some other switching devices or components. This loading may decrease signal integrity of signals on the CAN bus, adversely affecting operation of the CAN devices coupled to the CAN bus. Generally, at least some switches of a CAN device remain on, or conductive, even in the event of a loss of arbitration, thereby causing the parasitic capacitance described above to be present on the CAN bus. However, by turning off the DEPMOS for CAN devices that lose arbitration, the capacitance on the CAN bus may be reduced. Some approaches for turning off the DEPMOS to reduce the capacitance on the CAN bus rely on discharging a gate voltage of the DEPMOS via a resistor in the event of an arbitration loss. However, this approach may consume an amount of time that is insufficient to turn off the DEPMOS prior to completion of a transmission on the CAN bus from the CAN device winning arbitration. Thus, despite the DEPMOS being turned off, the effects of the capacitive loading on the CAN bus may adversely affect communication from the CAN device winning arbitration because the DEPMOS is not turned off in a rapid enough manner to mitigate the capacitive loading during the time in which the CAN device winning arbitration is transmitting.

Examples of this description provide for detection of an arbitration loss by a CAN device. Responsive to determining that the CAN device has lost the arbitration, the CAN device may disable one or more components of the CAN device. For example, the CAN device may disable one or more components of a transmitter of the CAN device, such as one or more transistors. In an example, the transistor(s) may be DEPMOS transistors through which the CAN device couples to a CAN bus. In some examples, the CAN device may be a differential device such that a first DEPMOS couples the CAN device to a first differential signaling line of a CAN bus and a second DEPMOS couples the CAN device to a second differential signaling line of the CAN bus. In such an example, both the first and the second DEPMOS may be disabled by the CAN device responsive to the CAN device determining that it has lost arbitration on the CAN bus.

To determine whether the CAN device has lost the arbitration, in some examples, the CAN device includes an arbitration detection circuit. The arbitration detection circuit is configured to, or include components coupled in an architecture to, compare data bits on transmit and receive terminals of the CAN device. Responsive to the data bits matching (e.g., having a same logical value), the CAN device may determine, via the arbitration detection circuit, that it has not lost arbitration on the CAN bus. Conversely, responsive to a mismatch between the data bits, the CAN device may determine, via the arbitration detection circuit, that the CAN device has lost arbitration on the CAN bus. In some examples, a delay may exist between data values being provided on the transmit and receive terminals of the CAN device, thereby causing a resulting error in the arbitration detection. To mitigate the occurrence of such an error, the arbitration detection circuit may include error mitigation circuitry, such as a filter.

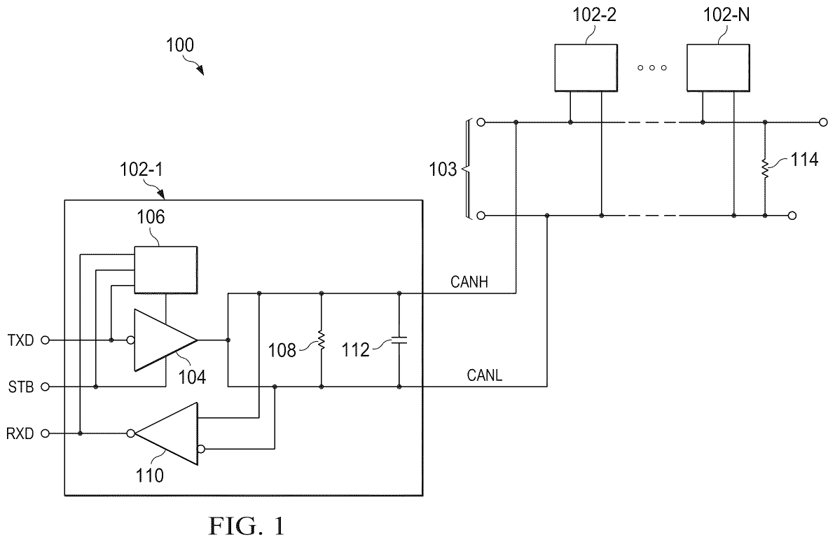

FIG. 1 is a block diagram of an example system 100 implementing a CAN. In an example, the system 100 includes CAN transceivers 102-1, 102-2, . . . 102-N each coupled to a CAN bus 103. The CAN transceiver 102-1 includes a driver 104, an arbitration detection circuit 106, an impedance element 108, a comparator 110, and a capacitor 112. In some examples, the impedance element 108 is a resistor that functions as a load, terminating the CAN bus 103 at the CAN transceiver 102-1. Similarly, in some examples the capacitor 112 is a load capacitor. Although not shown in FIG. 1, in some examples, a parasitic capacitance may be provided on the CAN bus 103, such as between or on differential signaling lines of the CAN bus 103. The parasitic capacitance may be caused by capacitive loading by components of the CAN transceiver 102-1, such as the driver 104 and/or components (not shown) of the driver 104. Although detailed components are shown only for the CAN transceiver 102-1 in FIG. 1, and operation is described herein generally with respect to the CAN transceiver 102-1, each of the other CAN transceivers 102 may have an architecture substantially like that of the CAN transceiver 102-1 and may function substantially like the CAN transceiver 102-1.

In an example of architecture of the system 100, the CAN transceiver 102-1 has first and second differential CAN bus (CANH and CANL) terminal (which may be bidirectional, functioning as both transmit and receive terminals), a transmit data input (TXD) terminal, a receive data output (RXD) terminal, and a standby control input (STB) terminal. Although not shown in FIG. 1, in various examples the CAN transceiver 102-1 may have other terminals, such as for coupling the CAN transceiver 102-1 to a ground terminal at which a ground voltage potential is provided, a voltage supply terminal at which a supply voltage is provided, or the like. In an example, the driver 104 has an input terminal coupled to the TXD input. In some examples, the input terminal of the driver 104 may be an inverted input terminal. The driver 104 further has first and second output terminals. In some examples, the second output terminal of the driver 104 is an inverted output terminal. The first output terminal of the driver 104 may be coupled to the CANH terminal and the second output terminal of the driver may be coupled to the CANL terminal. In an example, the CAN transceiver 102-1 couples to the CAN bus 103 at the CANH and CANL terminals. The arbitration detection circuit 106 has a first input terminal coupled to the TXD terminal, a second input terminal coupled to the RXD terminal, a third input terminal coupled to the STB terminal, and has an output terminal. Although shown as a separate component, in some examples, the arbitration detection circuit 106 is included in (e.g., implemented as a component of) the driver 104. In an example, the output terminal of the arbitration detection circuit 106 is coupled to the driver 104, such as to control conductivity of a DEPMOS (not shown) of the driver 104. The impedance element 108 has a first terminal coupled to the CANH terminal and a second terminal coupled to the CANL terminal. The comparator 110 has a first input terminal coupled to the CANH terminal, a second input terminal coupled to the CANL terminal, and an output terminal coupled to the RXD terminal. In some examples, the second input terminal of the comparator 110, the output terminal of the comparator 110, or both, may be inverted terminals. The capacitor 112 may have a first terminal coupled to the RXD terminal and a second terminal coupled to ground terminal. In some examples, an impedance element 114, such as a resistor, terminates the CAN bus 103, such as by having a first terminal coupled to a first differential signaling line of the CAN bus 103 and having a second terminal coupled to a second differential signaling line of the CAN bus 103.

In an example of operation of the system 100, the CAN transceiver 102-1 broadcasts a message on the CAN bus 103. In some examples, a second CAN transceiver 102, such as the CAN transceiver 102-2, also attempts to broadcast a message on the CAN bus 103 simultaneously with the CAN transceiver 102-1. In such an example, arbitration is performed among the CAN transceivers 102 such that the CAN transceiver 102 having a higher priority (e.g., the CAN transceiver 102-2) continues transmitting while the CAN transceiver having a lower priority (e.g., the CAN transceiver 102-1) ceases transmitting. For example, the arbitration detection circuit 106 may compare data provided at the TXD terminal of the CAN transceiver 102-1 and at the RXD terminal of the CAN transceiver 102-1. Responsive to determining that a mismatch exists between the data, the CAN transceiver 102-1 determines that it lost arbitration to the CAN transceiver 102-2.

For example, each CAN transceiver 102 may begin a message with an identifier that uniquely identifies that respective CAN transceiver 102 coupled to the CAN bus 103 in the system 100. The identifier may have a correlation to a relative priority of the CAN transceivers 102 such that a CAN transceiver 102 having a smaller value identifier has a higher priority over a CAN transceiver 102 having a higher value identifier in the system 100. In this way, a CAN transceiver 102 that has a lower priority may transmit a logic 1 value of its identifier on the CAN bus 103 while a CAN transceiver 102 that has a higher priority may transmit a logic 0 value of its identifier on the CAN bus 103. The arbitration detection circuit 106 may compare the transmitted and received data of the CAN transceiver 102-1 to determine that the CAN transceiver 102-1 is transmitting a logic 1 value of its identifier but a logic 0 value is provided at the RXD terminal of the CAN transceiver 102-1. In this way, the CAN transceiver 102-1 determines that the CAN transceiver 102-1 has lost arbitration to broadcast on the CAN bus 103 to another CAN transceiver 102, such as the CAN transceiver 102-2.

In some examples, propagation delays or other errors in the system 100 may result in a delay between transmission by the CAN transceiver 102-1 of a value of its identifier and receipt by the CAN transceiver 102-1 of that corresponding value at its RXD terminal. This may result in false detections, such as indicating that the CAN transceiver 102-1 has lost arbitration to another CAN transceiver 102, when in fact, the CAN transceiver 102-1 may not have yet lost arbitration. To mitigate such delay-based errors, in some examples, the arbitration detection circuit 106 includes a filter (not shown). The filter functions as a delay element that creates a delayed representation of the comparison of the values provided at the TXD and RXD terminals of the CAN transceiver 102-1. In some examples, the filter is implemented as a resistor-capacitor (RC) filter such that an output value of the filter varies with time as a capacitor of the filter is charged. Responsive to the charge on the capacitor increasing to exceed a threshold value, a logic 1 value is asserted; otherwise, a logic 0 value results from the filter. The logic value resulting from the filter may be compared to a current (e.g., substantially non-delayed) result of the comparison between the values provided at the TXD and RXD terminals of the CAN transceiver 102-1. Responsive to both the logic value resulting from the filter and the result of the comparison between the values provided at the TXD and RXD terminals of the CAN transceiver 102-1 having values of logic 1, the arbitration detection circuit 106 may control the driver 104 to disable one or more components, reducing a parasitic capacitance provided on the CAN bus 103 resulting from the CAN transceiver 102-1. For example, the arbitration detection circuit 106 may control a DEPMOS of the driver 104 to become non-conductive in a forward direction, reducing a parasitic capacitance provided on the CAN bus 103 resulting from the DEPMOS. Responsive to the data provided at the TXD terminal of the CAN transceiver 102-1 having a value of logic 0, the arbitration detection circuit 106 may control the driver 104 to enable one or more components. For example, the arbitration detection circuit 106 may control a DEPMOS of the driver 104 to become conductive in a forward direction, such as by decreasing a voltage of a signal provided at a gate of the DEPMOS.

In this way, by determining whether the CAN transceiver 102-1 has won or lost arbitration with another CAN transceiver 102 for broadcasting on the CAN bus 103, the arbitration detection circuit 106 may increase signal integrity on the CAN bus 103. For example, responsive to determining that the CAN transceiver 102-1 has lost the arbitration, the arbitration detection circuit 106 may provide one or more control signals that reduces a parasitic capacitance provided on the CAN bus 103 resulting from the CAN transceiver 102-1. As a result, signal integrity of the CAN bus 103 and performance of the CAN transceivers 102 related to a message broadcast by the CAN transceiver 102 which won the arbitration are both increased.

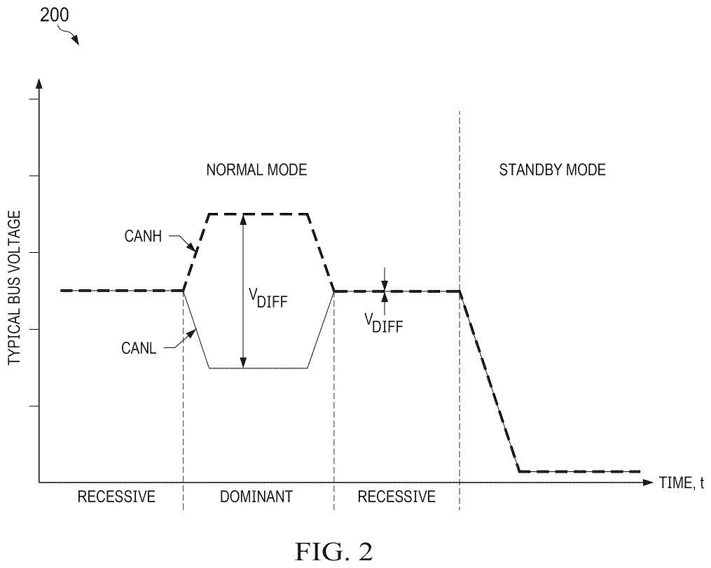

FIG. 2 is a diagram 200 of example CAN communication, such as by the CAN transceiver 102-1. The diagram may be representative of a voltage provided on the CAN bus 103, and correspondingly at CANH and CANL terminals of a CAN transceiver 102, during operation of the system 100 in both normal and standby modes. As shown by the diagram 200, the CAN bus 103 may be driven recessively or dominantly. While driven recessively, a differential voltage (V_{DIFF}) across the differential signaling lines of the CAN bus 103 is less than the differential voltage across the differential signaling lines of the CAN bus 103 while the CAN bus 103 is driven dominantly. For example, a differential voltage across the differential signaling lines of the CAN bus 103 while driven recessively may be approximately zero, and the differential voltage across the differential signaling lines of the CAN bus 103 while the CAN bus 103 is driven dominantly may be approximately equal to two times a supply voltage of the CAN transceivers 102. In other examples, the differential voltage across the differential signaling lines of the CAN bus 103 while the CAN bus 103 is driven dominantly may have any suitable proportional relationship to the supply voltage of the CAN transceivers 102. In an example, a recessive transmission on the CAN bus 103 corresponds to a data value of logic 1, and a dominant transmission on the CAN bus 103 corresponds to a data value of logic 0. As further shown by the diagram 200, the differential voltage across the differential signaling lines of the CAN bus 103 while in the standby mode may also be approximately zero but having a lower common mode voltage than the differential voltage across the differential signaling lines of the CAN bus 103 while driven recessively in the normal mode.

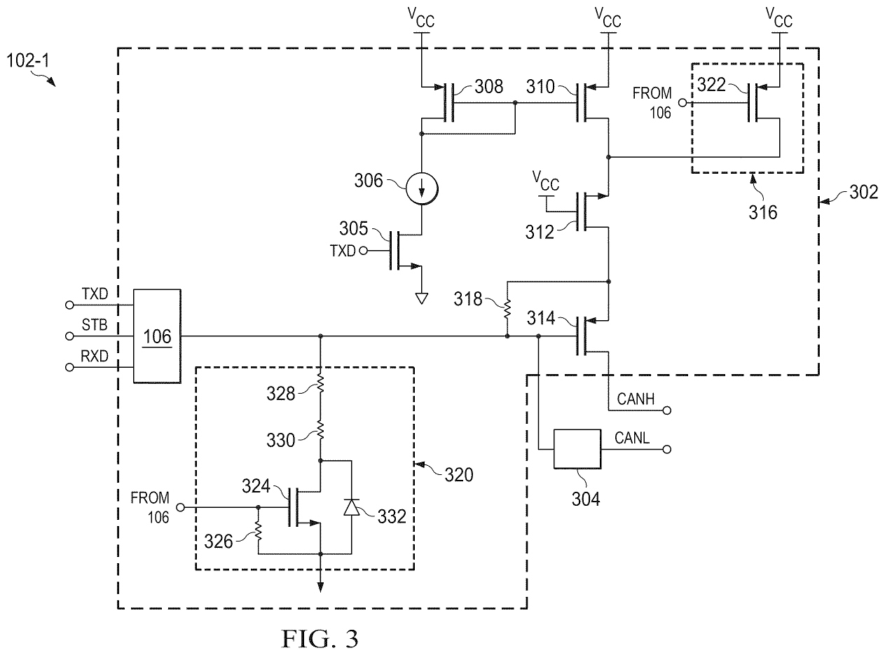

FIG. 3 is a schematic diagram of an example CAN transceiver 102-1. In an example, the CAN transceiver 102-1 includes the driver 104 and the arbitration detection circuit 106, as described above. In an example, the driver 104 includes a first differential portion 302 and a second differential portion 304. The first differential portion 302 includes a transistor 305, a current source 306, a transistor 308, a transistor 310, a transistor 312, and a transistor 314. In some examples, the transistor 314 is the DEPMOS, as described above herein. In an example, the first differential portion 302 may be for driving a first differential signaling line of the CAN bus 103, such as via the CANH terminal of the CAN transceiver 102-1, as described above. The second differential portion 304 may be for driving a second differential signaling line of the CAN bus 103, such as via the CANL terminal of the CAN transceiver 102-1, as described above. As such, the first differential portion 302 and the second differential portion 304 may be complementary with parameter matched components. Accordingly, while the first differential portion 302 is described in detail herein, the second differential portion 304 is not but its architecture and function may be understood from the description of the first differential portion 302. In some examples, the CAN transceiver 102-1 further includes a pull-up circuit 316, a resistor 318, and a pull-down circuit 320. In an example, the pull-up circuit 316 includes a transistor 322. In an example, the pull-down circuit 320 includes a transistor 324, a resistor 326, a resistor 328, a resistor 330, and a diode 332. In some examples, the diode 332 is a Zener diode.

In an example architecture of the CAN transceiver 102-1, the transistor 305 has a control terminal and first and second terminals, in which TXD is provided at the control terminal of the transistor 305, and the second terminal of the transistor 305 is coupled to a ground terminal. The current source 306 has first and second terminals, the second terminal of the current source 306 coupled to the first terminal of the transistor 305. The transistor 308 has a first terminal coupled to a voltage supply terminal, a second terminal coupled to the first terminal of the current source 306 and has a control terminal coupled to the first terminal of the current source 306. The transistor 310 has a first terminal coupled to the voltage supply terminal, has a second terminal, and has a control terminal coupled to the first terminal of the current source 306. In an example, the transistor 308 and the transistor 310 form a current mirror such that an amount of current flowing through the transistor 310 is proportional to an amount of current flowing through the transistor 308. The transistor 312 has a first terminal coupled to the second terminal of the transistor 310, has a second terminal, and has a control terminal coupled to the voltage supply terminal. The transistor 314 has a first terminal coupled to the second terminal of the transistor 312, has a second terminal coupled to the CANH terminal of the CAN transceiver 102-1, and has a control terminal coupled to the output terminal of the arbitration detection circuit 106.

The pull-up circuit 315 has a first terminal coupled to the voltage supply terminal and has a second terminal coupled to the first terminal of the transistor 312. For example, the transistor 322 has a first terminal coupled to the voltage supply terminal, a second terminal coupled to the first terminal of the transistor 312 and has a control terminal coupled to the output terminal of the arbitration detection circuit 106. The resistor 318 has a first terminal coupled to the first terminal of the transistor 314 and has a second terminal coupled to the control terminal of the transistor 314. The pull-down circuit 320 has a first terminal coupled to the control terminal of the transistor 314 and has a second terminal coupled to a ground terminal. For example, the transistor 324 has a first terminal, has a second terminal coupled to the ground terminal, and has a control terminal coupled to the output terminal of the arbitration detection circuit 106. The resistor 326 has a first terminal coupled to the control terminal of the transistor 324 and has a second terminal coupled to the ground terminal. The resistor 328 has a first terminal coupled to the control terminal of the transistor 314 and has a second terminal. The resistor 330 has a first terminal coupled to the second terminal of the resistor 328 and has a second terminal coupled to the first terminal of the transistor 324. The diode 332 has an anode coupled to the ground terminal and has a cathode coupled to the first terminal of the transistor 324.

In an example of operation of the CAN transceiver 102-1, by providing a signal approximately equal in value to the voltage supply at the control terminal of the transistor 312, the transistor 312 is held in a conductive state in the forward direction. In some examples, the transistor 312 may be referred to as an “always-on” device, which is in a forward conductive state if the CAN transceiver 102-1 is powered an operational. The transistor 305 receives TXD and, based on a value of TXD, enters a conductive or non-conductive state. For example, responsive to TXD having a logic high value, the transistor 305 becomes conductive in a forward direction, causing current to sink from the control terminals of the transistors 308, 310 through the current source 306 and transistor 305 to the ground terminal. This action causes the transistor 310 to turn on and provide a logic high value (e.g., approximately equal to Vcc) at the first terminal of the transistor 314 to drive the CANH terminal (and therefore CANH differential signaling line of the CAN bus 103) dominantly. Conversely, responsive to TXD having a logic low value, the transistor 305 becomes non-conductive in the forward direction, causing the transistors 308, 310 to turn off, or become non-conductive in the forward direction. This action causes a logic low value (e.g., approximately equal to a ground voltage potential) to be provided at the first terminal of the transistor 314 to drive the CANH terminal (and therefore CANH differential signaling line of the CAN bus 103) recessively.

In some examples, the CAN transceiver 102-1 performs arbitration based on values received at the TXD terminal to determine whether the CAN transceiver 102-1 my continue, or should cease, driving the CAN bus 103. For example, responsive to the presence of logic low values or logic high values at both the TXD and RXD terminals of the CAN transceiver 102-1, the arbitration detection circuit 106 controls the transistor 314, 324 to turn, or remain, on or conductive in the forward direction. The arbitration detection circuit 106 further controls the transistor 322 to turn, or remain, off or non-conductive in the forward direction. Responsive to the presence of a logic low value at one of the TXD or RXD terminals of the CAN transceiver 102-1 and a logic high value at the other of the TXD or RXD terminals of the CAN transceiver 102-1, the arbitration detection circuit 106 determines that the CAN transceiver 102-1 has lost arbitration on the CAN bus 103. Responsive to determining that the CAN transceiver 102-1 has lost arbitration on the CAN bus 103, the arbitration detection circuit 106 controls the transistors 314, 324 to turn off or become non-conductive in the forward direction and controls the transistor 322 to turn on or become conductive in the forward direction.

By controlling the transistor 322 to turn on, the arbitration detection circuit 106 causes the transistor 322 to precharge the first terminal of the transistor 314. By precharging the first terminal of the transistor 314, the transistor 322 causes a controlled value (e.g., approximately Vcc) to be provided at the first terminal of the transistor 314. This may prevent the first terminal of the transistor 314 from being a floating terminal, which may increase the capacitance presented by the transistor 314 on the CAN bus 103.

In some examples, the pull-down circuit 320 pulls-down the control terminal of the transistor 314 to a value approximately equal to the ground voltage potential, such as to provide a strong turn-on of the transistor 314. The pull-down circuit 320 may provide the strong pull-down in the absence of a determination that the CAN transceiver 102-1 has lost arbitration. For example, responsive to the arbitration detection circuit 106 determining that arbitration has not been lost, the arbitration detection circuit 106 controls the transistor 324 to turn on or be conductive in a forward direction. This creates a conductive path from the control terminal of the transistor 314, through the resistors 328, 330 and the transistor 324 to the ground terminal at which the ground voltage potential is provided. Conversely, responsive to the arbitration detection circuit 106 determining that arbitration has been lost, the arbitration detection circuit 106 controls the transistor 324 to turn off or be non-conductive in the forward direction. This cuts off the conductive path from the control terminal of the transistor 314, through the resistors 328, 330 and the transistor 324 to the ground terminal at which the ground voltage potential is provided, thereby causing the transistor 314 to also become non-conductive in the forward direction.

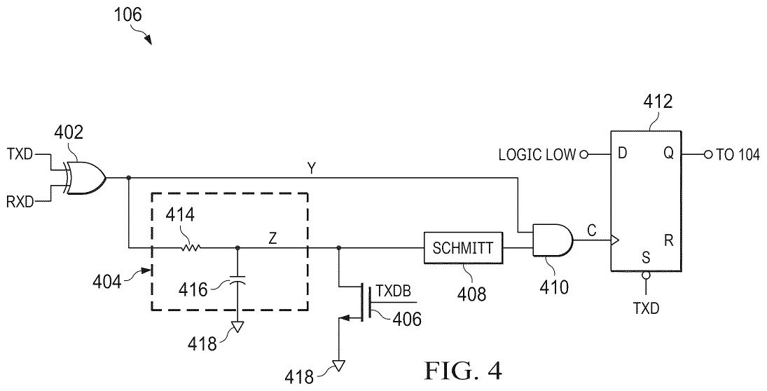

FIG. 4 is a schematic diagram of an example arbitration detection circuit 106. In an example, the arbitration detection circuit 106 includes an exclusive-OR (XOR) logic circuit 402, a filter 404, a transistor 406, a Schmitt trigger 408, an AND logic circuit 410, and a D flip flop 412. In some examples, the filter 404 is a RC filter including a resistor 414 and a capacitor 416. The D flip flop 412 may be a set-reset type D flip flop.

In an example architecture of the arbitration detection circuit 106, the XOR logic circuit 402 has a first input terminal coupled to the TXD terminal of the CAN transceiver 102-1, has a second input terminal coupled to the RXD terminal of the CAN transceiver 102-1, and has an output terminal. The filter 404 has an input terminal coupled to the output terminal of the XOR logic circuit 402 and has an output terminal. For example, the resistor 414 has a first terminal coupled to the output terminal of the XOR logic circuit 402 and has a second terminal, and the capacitor 416 has a first terminal coupled to the second terminal of the resistor 414 and has a second terminal coupled to a ground terminal 418. The transistor 406 has a first terminal coupled to the output terminal of the filter 404 (e.g., the second terminal of the capacitor 416), a second terminal coupled to the ground terminal 418, and has a control terminal coupled to a terminal at which a signal TXDB is provided. The Schmitt trigger 408 has an input terminal coupled to the output terminal of the filter 404 and has an output terminal. The AND logic circuit 410 has a first input terminal coupled to the output terminal of the XOR logic circuit 402, a second input terminal coupled to the output terminal of the Schmitt trigger 408, and has an output terminal. The D flip flop 412 has a data input terminal at which a logic low value is provided, such as by coupling the data input terminal to the ground terminal 418. The D flip flop 412 also has a clock input terminal coupled to the output terminal of the AND logic circuit 410, a set input terminal coupled to the TXD terminal of the CAN transceiver 102-1, a reset input terminal, and an output terminal. In an example, the output terminal of the D flip flop 412 is coupled to the driver 104, such as to control one or more components of the driver 104. For example, the output terminal of the D flip flop 412 may be coupled to gate terminals of any one or more of the transistors 314, 322, 324. In some examples, the set input terminal of the D flip flop 412 may be an inverted, or active low, terminal.

In an example of operation of the arbitration detection circuit 106, responsive to a logic high value being provided at one and only one of the TXD terminal of the CAN transceiver 102-1 or the RXD terminal of the CAN transceiver 102-1, the XOR logic circuit 402 provides an output signal, represented in FIG. 4 as signal Y, having a logic high value. Otherwise, the XOR logic circuit 402 provides the output signal Y having a logic low value. The filter 404 filters the output signal Y to form a filtered signal, represented in FIG. 4 as signal Z. In this way, signal Z may be a delayed representation of output signal Y, delayed based on a time constant (e.g., an RC time constant) of the filter 404. Responsive to signal Z increasing in value to exceed a first threshold value, the Schmitt trigger provides a trigger output having a logic high value. Conversely, responsive to signal Z decreasing in value to be less than a second threshold value, the Schmitt trigger provides the trigger output having a logic low value. Responsive to a logic low value being provided at the TXD terminal of the CAN transceiver 102-1, the transistor 406 may become conductive, discharging signal Z to the ground terminal 418. In this way, the output of the filter 404 may be cleared or reset, such as to mitigate the occurrence of false edges in the trigger output.

The AND logic circuit 410 compares the output signal Y to the trigger output and, only responsive to both the output signal Y to the trigger output having logic high values, provides an output signal, represented in FIG. 4 as signal C, having a logic high value. Otherwise, the AND logic circuit 410 provides the output signal C having a logic low value. In an example, a default output of the D flip flop 412 may have a logic low value, such as resulting from the logic low value being provided at the data input terminal of the D flip flop 412. Responsive to the output signal C having a logic high value, the logic low value being provided at the data input terminal of the D flip flop 412 may be provided as the output signal of the D flip flop 412. In an example, the output signal of the D flip flop 412 having a logic low value may indicate that the arbitration detection circuit 106 has determined that the CAN transceiver 102-1 has lost arbitration on the CAN bus 103, that the transistor 314 should be controlled to be disabled or made non-conductive in a forward direction, and/or that the transistor 322 should be controlled to be enabled or made conductive in a forward direction.

Responsive to a logic low value being provided at the TXD terminal of the CAN transceiver 102-1, the D flip flop 412 may provide its output signal having a logic high value. In an example, the output signal of the D flip flop 412 having a logic low value may indicate that the arbitration detection circuit 106 has determined that the CAN transceiver 102-1 has not lost arbitration on the CAN bus 103, the transistor 314 should be controlled to be enabled or made conductive in the forward direction, and/or that the transistor 322 should be controlled to be disabled or made non-conductive in the forward direction. Responsive to a logic high value being provided at the STB terminal of the CAN transceiver 102-1, the D flip flop 412 may provide the output signal of the D flip flop 412 having a logic low value.

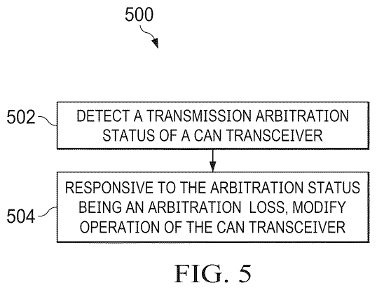

FIG. 5 is a flowchart of an example method 500 of parasitic capacitance reduction of a CAN transceiver. For example, a CAN transceiver, such as the CAN transceiver 102-1, may implement the method 500 to reduce a parasitic capacitance presented by that CAN transceiver on a CAN bus, such as the CAN bus 103, to which the CAN transceiver is coupled. By reducing the parasitic capacitance presented by the CAN transceiver on the CAN bus to which the CAN transceiver is coupled, the CAN transceiver may increase signal integrity of a signal on the CAN bus as seen by other devices coupled to the CAN bus, thereby improving performance of the other devices coupled to the CAN bus and an overall system that includes the CAN bus. In at least some examples, the CAN transceiver includes an arbitration detection circuit and implements the method 500 at least in part via the arbitration detection circuit. The arbitration detection circuit may be of any suitable architecture, such as that of the arbitration detection circuit 106 described above, a digital logic circuit, a mixed analog and digital logic circuit, a controller, processor, or other circuit, or the like.

At operation 502, the arbitration detection circuit detects a transmission arbitration status of the CAN transceiver. For example, the arbitration detection circuit detects or determines whether the CAN transceiver has lost arbitration on the CAN bus. In some examples, detecting the transmission arbitration status of the CAN transceiver includes determining whether a transmit data input signal (e.g., a signal received at a TXD terminal of the CAN transceiver) and a receive data output signal (e.g., a signal provided at a RXD terminal of the CAN transceiver) match or do not match in value. In an example, the arbitration detection circuit detects or determines that an arbitration loss has occurred responsive to a mismatch in values between the transmit data input signal and the receive data output signal.

At operation 504, responsive to the arbitration status being an arbitration loss, the arbitration detection circuit modifies operation of the CAN transceiver. In some examples, modifying the operation of the CAN transceiver includes disabling an output transistor of the CAN transceiver. In some examples, the output transistor is a component of a driver of the CAN transceiver, such as a DEPMOS (e.g., the transistor 314), described above herein. Otherwise, such as in the absence of a determination of an arbitration loss (or other reset condition, such as receipt of an asserted standby signal), the arbitration detection circuit enables the output transistor of the CAN transceiver. In at least some examples, disabling the output transistor of the CAN transceiver reduces a capacitance provided on the CAN bus, such as a parasitic capacitance provided on the CAN bus resulting from conductivity the output transistor. In some examples, this capacitance may also be referred to as a bus capacitance, such as an input bus capacitance of the CAN transceiver. In other examples, modifying the operation of the CAN transceiver includes changing a drive strength with which the CAN transceiver drives the CAN bus recessively, reducing current consumption of the CAN transceiver responsive to detection of the arbitration loss, or any other suitable action.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

While certain components may be described herein as being of a particular process technology, these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground voltage potential” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component. Furthermore, a voltage rail or more simply a “rail,” may also be referred to as a voltage terminal and may generally mean a common node or set of coupled nodes in a circuit at the same potential.

What is claimed is:

1. A circuit, comprising:
a first transistor having a control terminal and first and second terminals;
a second transistor having a control terminal and first and second terminals, the first terminal of the second transistor coupled to the second terminal of the first transistor;
a first resistor having first and second terminals, the first terminal of the first resistor coupled to the control terminal of the second transistor, and the second terminal of the first resistor coupled to the first terminal of the second transistor;
a digital logic circuit having an output terminal and first and second input terminals, the output terminal of the digital logic circuit coupled to the control terminal of the second transistor, the first input terminal of the digital logic circuit coupled to a data transmit input terminal of the circuit, and the second input terminal of the digital logic circuit coupled to a data receive output terminal of the circuit.

2. The circuit of claim 1, wherein the circuit is a portion of a controller area network (CAN) transceiver.

3. The circuit of claim 1, wherein the digital logic circuit includes:
an exclusive OR (XOR) logic circuit having an output terminal and first and second input terminals;
a second resistor having first and second terminals, the first terminal of the second resistor coupled to the output terminal of the XOR logic circuit;
a capacitor having first and second terminals, the first terminal of the resistor coupled to the second terminal of the second resistor, and the second terminal of the capacitor coupled to a ground terminal;
a third transistor having a control terminal and first and second terminals, the first terminal of the third transistor coupled to the second terminal of the second resistor, and the second terminal of the third transistor coupled to the ground terminal;
a Schmitt trigger having input and output terminals, the input terminal of the Schmitt trigger coupled to the second terminal of the second resistor;
an AND logic circuit having an output terminal and first and second input terminals, the first input terminal of the AND logic circuit coupled to the output terminal of the XOR logic circuit, and the second input terminal of the AND logic circuit coupled to the output terminal of the Schmitt trigger; and
a flip-flop having a data input terminal, a clock input terminal, a set input terminal, and a data output terminal, the clock input terminal coupled to the output terminal of the AND logic circuit, and the data output terminal coupled to the control terminal of the second transistor.

4. The circuit of claim 3, wherein the digital logic circuit is configured to receive a transmit data signal at the first input terminal of the XOR logic circuit and the set input terminal of the flip-flop, a receive data signal at the second input terminal of the XOR logic circuit, an inverse of the transmit data signal at the control terminal of the third transistor, and a logic level low signal at the data input terminal of the flip-flop.

5. The circuit of claim 1, further comprising a third transistor having a control terminal and first and second terminals, the control terminal of the third transistor coupled to the output terminal of the digital logic circuit, the first terminal of the third transistor coupled to a supply voltage terminal, and the second terminal of the third transistor coupled to the control terminal of the second transistor.

6. The circuit of claim 1, further comprising a third transistor having a control terminal and first and second terminals, the control terminal of the third transistor coupled to the output terminal of the digital logic circuit, the first terminal of the third transistor coupled to a supply voltage terminal, and the second terminal of the third transistor coupled to the first terminal of the first transistor.

7. The circuit of claim 6, further comprising a fourth transistor having a control terminal and first and second terminals, the control terminal of the fourth transistor coupled to the output terminal of the digital logic circuit, the first terminal of the fourth transistor coupled to a supply voltage terminal, and the second terminal of the fourth transistor coupled to the control terminal of the second transistor.

8. The circuit of claim 1, further comprising:
a third transistor having a control terminal and first and second terminals, the first terminal of the third transistor coupled to a supply voltage terminal; and
a fourth transistor having a control terminal and first and second terminals, the control terminal of the third transistor coupled to the control terminal of the fourth transistor, the first terminal of the fourth transistor coupled to a supply voltage terminal, and the second terminal of the fourth transistor coupled to the first terminal of the first transistor.

9. The circuit of claim 1, further comprising a receiver circuit coupled to the second terminal of the second transistor.

10. A circuit, comprising:
a first transistor having a control terminal and first and second terminals;
a second transistor having a control terminal and first and second terminals, the first terminal of the second transistor coupled to the second terminal of the first transistor;
a first resistor having first and second terminals, the first terminal of the first resistor coupled to the control terminal of the second transistor, and the second terminal of the first resistor coupled to the first terminal of the second transistor;
a digital logic circuit having an output coupled to the control terminal of the second transistor, the digital logic circuit configured to:
detect an arbitration loss or win by the circuit;
responsive to detecting an arbitration loss, provide a gate control signal having a logic high value to the control terminal of the second transistor;
responsive to not detecting an arbitration loss, or to detecting an arbitration win, provide the gate control signal having a logic low value to the control terminal of the second transistor;
a pull-up circuit configured to, responsive to the gate control signal having the logic low value, pull up the first terminal of the first transistor to a supply voltage to precharge the first terminal of the second transistor; and
a pull-down circuit configured to, responsive to the gate control signal having the logic high value, pull down the control terminal of the second transistor to a specified voltage.

11. The circuit of claim 10, wherein the specified voltage is a Zener diode voltage.

12. The circuit of claim 10, wherein the digital logic circuit includes:
an exclusive OR (XOR) logic circuit having an output terminal and first and second input terminals;
a second resistor having first and second terminals, the first terminal of the second resistor coupled to the output terminal of the XOR logic circuit;
a capacitor having first and second terminals, the first terminal of the resistor coupled to the second terminal of the second resistor, and the second terminal of the capacitor coupled to a ground terminal;
a third transistor having a control terminal and first and second terminals, the first terminal of the third transistor coupled to the second terminal of the second resistor, and the second terminal of the third transistor coupled to the ground terminal;
a Schmitt trigger having input and output terminals, the input terminal of the Schmitt trigger coupled to the second terminal of the second resistor;
an AND logic circuit having an output terminal and first and second input terminals, the first input terminal of the AND logic circuit coupled to the output terminal of the XOR logic circuit, and the second input terminal of the AND logic circuit coupled to the output terminal of the Schmitt trigger; and
a flip-flop having a data input terminal, a clock input terminal, a set input terminal, and a data output terminal, the clock input terminal coupled to the output terminal of the AND logic circuit, and the data output terminal coupled to the control terminal of the second transistor.

13. The circuit of claim 12, wherein the digital logic circuit is configured to receive a transmit data signal at the first input terminal of the XOR logic circuit and the set input terminal of the flip-flop, a receive data signal at the second input terminal of the XOR logic circuit, an inverse of the transmit data signal at the control terminal of the third transistor, and a logic level low signal at the data input terminal of the flip-flop.

14. A method implemented in a communication transceiver, the method comprising:
detecting a transmission arbitration status of the communication transceiver; and
responsive to the arbitration status being an arbitration loss, modifying operation of the communication transceiver.

15. The method of claim 14, wherein detecting the arbitration status includes determining that the arbitration loss has occurred responsive to a mismatch in values between a transmit data input signal and a receive data output signal.

16. The method of claim 14, wherein the communication transceiver includes an arbitration detection logic circuit configured to detect the transmission arbitration status of the communication transceiver, the arbitration detection logic circuit comprising:
an exclusive OR (XOR) logic circuit having an output terminal and first and second input terminals;
a resistor having first and second terminals, the first terminal of the resistor coupled to the output terminal of the XOR logic circuit;
a capacitor having first and second terminals, the first terminal of the resistor coupled to the second terminal of the resistor, and the second terminal of the capacitor coupled to a ground terminal;
a transistor having a control terminal and first and second terminals, the first terminal of the transistor coupled to the second terminal of the resistor, and the second terminal of the transistor coupled to the ground terminal;
a Schmitt trigger having input and output terminals, the input terminal of the Schmitt trigger coupled to the second terminal of the resistor;
an AND logic circuit having an output terminal and first and second input terminals, the first input terminal of the AND logic circuit coupled to the output terminal of the XOR logic circuit, and the second input terminal of the AND logic circuit coupled to the output terminal of the Schmitt trigger; and
a flip-flop having a data input terminal, a clock input terminal, a set input terminal, and a data output terminal, the clock input terminal coupled to the output terminal of the AND logic circuit, and the data output terminal coupled to the control terminal of the second transistor.

17. The method of claim 16, wherein the digital logic circuit is configured to receive a transmit data input signal at the first input terminal of the XOR logic circuit and the set input terminal of the flip-flop, a receive data output signal at the second input terminal of the XOR logic circuit, an inverse of the transmit data input signal at the control terminal of the third transistor, and a logic level low signal at the data input terminal of the flip-flop.

18. The method of claim 17, wherein the resistor and the capacitor comprise a glitch filter configured to form a filtered signal by filtering an output signal of the XOR logic circuit to mitigate signal glitches resulting from a delay between the transmit data input signal and the receive data output signal.

19. The method of claim 18, further comprising, responsive to the transmit data input signal having a logic low value, discharging the filtered output signal of the XOR logic circuit to the ground terminal;
determining, via the AND logic circuit, an AND logic output signal based on the output signal of the XOR logic circuit and the filtered signal; and
determining, via the flip-flop, a gate control signal for controlling the output transistor of the communication transceiver, wherein the flip-flop receives the AND logic output signal at a clock input of the flip-flop.

20. The method of claim 18, wherein modifying operation of the communication transceiver includes disabling an output transistor of the communication transceiver, wherein the disabling reduces an input bus capacitance of the communication transceiver.
